(19) United States
(12) Patent Application Publication
(10) Pub. No.: US 2023/0040906 A1
(43) Pub. Date: Feb. 9, 2023

(54) PHOTOELECTRIC CONVERSION FILM, DISPERSION LIQUID, PHOTODETECTOR ELEMENT, AND IMAGE SENSOR

(71) Applicant: FUJIFILM Corporation, Tokyo (JP)

(72) Inventor: Masashi ONO, Kanagawa (JP)

(73) Assignee: FUJIFILM Corporation, Tokyo (JP)

(21) Appl. No.: 17/937,461

(22) Filed: Oct. 3, 2022

Related U.S. Application Data
(63) Continuation of application No. PCT/JP2021/014425, filed on Apr. 5, 2021.

(30) Foreign Application Priority Data
Apr. 7, 2020 (JP) 2020-068717

(51) Int. Cl. C09K 11/88; H01L 27/30; H01L 51/42; H01L 51/44; C09K 11/02

(52) U.S. Cl. CPC C09K 11/881; H01L 27/307; H01L 51/426; H01L 51/447; C09K 11/025; B82Y 20/00

(57) ABSTRACT

There are provided a photoelectric conversion film containing a quantum dot of a compound semiconductor that contains an Ag element, at least one element selected from an Sb element or a Bi element, and at least one element selected from an Se element or a Te element; a dispersion liquid that is used in the formation of the photoelectric conversion film; a photodetector element including the photoelectric conversion film; and an image sensor including the photodetector element.

### CROSS-REFERENCE TO RELATED APPLICATIONS

This application is a Continuation of PCT International Application No. PCT/JP2021/014425 filed on Apr. 5, 2021, which claims priority under 35 U.S.C § 119(a) to Japanese Patent Application No. 2020-068717 filed on Apr. 7, 2020. Each of the above application(s) is hereby expressly incorporated by reference, in its entirety, into the present application.

### BACKGROUND OF THE INVENTION

### 1. Field of the Invention

The present invention relates to a photoelectric conversion film containing quantum dots. In addition, the present invention relates to a dispersion liquid containing quantum dots, a photodetector element, and an image sensor.

### 2. Description of the Related Art

In recent years, attention has been focused on photodetector elements capable of detecting light in the infrared region in the fields such as smartphones, surveillance cameras, and in-vehicle cameras.

In the related art, a silicon photodiode in which a silicon wafer is used as a material of a photoelectric conversion layer has been used in a photodetector element that is used in an image sensor or the like. However, a silicon photodiode has low sensitivity in the infrared region having a wavelength of 900 nm or more.

In addition, an InGaAs-based semiconductor material known as a near-infrared light-receiving element has a problem in that it requires extremely high-cost processes such as epitaxial growth or a step of sticking a substrate in order to realize a high quantum efficiency, and thus it has not been widespread.

By the way, in recent years, research on quantum dots has been advanced. A solar battery cell having a photoelectric conversion film containing quantum dots of AgBiS₂ is described in Maria Bernechea, Nichole Cates Miller, Guillem Xercavins, David So, Alexandros Stavrinadis, and Gerasimos Konstantatos, “Solution-processed solar cells based on environmentally friendly AgBiS2 nanocrystals”, Nature Photonics, Vol 10, pp 521-525 (2016).

### SUMMARY OF THE INVENTION

In recent years, with the demand for performance improvement of an image sensor and the like, further improvement of various characteristics that are required in a photodetector element used in the image sensor and the like is also required. For example, one of the characteristics required in the photodetector element is to have a high external quantum efficiency with respect to light having a target wavelength to be detected by the photodetector element. In a case of increasing the external quantum efficiency of the photodetector element, it is possible to increase the accuracy of detecting light in the photodetector element.

As a result of diligently studying a semiconductor film used in a photoelectric conversion layer of the solar battery cell described in Maria Bernechea, Nichole Cates Miller, Guillem Xercavins, David So, Alexandros Stavrinadis, and Gerasimos Konstantatos, “Solution-processed solar cells based on environmentally friendly AgBiS2 nanocrystals”, Nature Photonics, Vol 10, pp 521-525 (2016), the inventors of the present invention found that the photoelectric conversion film containing quantum dots of AgBiS₂ has a low external quantum efficiency with respect to light having a wavelength in the infrared region (particularly, light having a wavelength of 900 nm or more), and a photodetector element using this photoelectric conversion film has insufficient detection accuracy with respect to the light having a wavelength in the infrared region.

Accordingly, an object of the present invention is to provide a novel photoelectric conversion film having a high external quantum efficiency with respect to light having a wavelength in the infrared region, a dispersion liquid, a photodetector element, and an image sensor.

As a result of carrying out diligent studies, the inventors of the present invention found that quantum dots of a compound semiconductor, which contain an Ag element, at least one element selected from an Sb element or a Bi element, and at least one element selected from an Se element or a Te element, has a small band gap, and a photoelectric conversion film including these quantum dots has a high external quantum efficiency with respect to light having a wavelength in the infrared region, thereby completing the present invention. As a result, the present invention provides the following aspects.
<1>A photoelectric conversion film comprising a quantum dot of a compound semiconductor that contains an Ag element, at least one element selected from an Sb element or a Bi element, and at least one element selected from an Se element or a Te element.
<2>The photoelectric conversion film according to <1>, in which the compound semiconductor contains an Ag element, a Bi element, and at least one element selected from an Se element or a Te element.
<3>The photoelectric conversion film according to <1>, in which the compound semiconductor contains an Ag element, a Bi element, and a Te element.
<4>The photoelectric conversion film according to any one of <1> to <3>, in which the compound semiconductor further contains an S element.
<5>The photoelectric conversion film according to <1>, in which the compound semiconductor contains an Ag element, at least one element selected from an Sb element or a Bi element, a Te element, and an S element, and a value obtained by dividing the number of the Te elements by a total of the number of the Te elements and the number of the S elements is 0.05 to 0.5.
<6>The photoelectric conversion film according to any one of <1> to <5>, in which a crystal structure of the compound semiconductor is a cubic system or a hexagonal system.
<7>The photoelectric conversion film according to any one of <1> to <6>, in which a band gap of the quantum dot is 1.2 eV or less.
<8>The photoelectric conversion film according to any one of<1>to <6>, in which a band gap of the quantum dot is 1.0 eV or less.
<9>The photoelectric conversion film according to any one of<1>to <8>, in which an average particle diameter of the quantum dots is 3 to 20 nm.
<10>The photoelectric conversion film according to any one of <1>to <9>, further comprising a ligand that is coordinated to the quantum dot.
<11>The photoelectric conversion film according to <10>, in which the ligand includes at least one selected from a ligand containing a halogen atom or a polydentate ligand containing two or more coordination moieties.
<12>The photoelectric conversion film according to <11>, in which the ligand containing a halogen atom is an inorganic halide.
<13>A dispersion liquid for forming a photoelectric conversion film, the dispersion liquid comprising:
a quantum dot of a compound semiconductor that contains an Ag element, at least one element selected from an Sb element or a Bi element, and at least one element selected from an Se element or a Te element;
a ligand that is coordinated to the quantum dot; and
a solvent.
<14>A photodetector element comprising the photoelectric conversion filmaccording to any one of <1>to <12>.
<15>An image sensor comprising the photodetector element according to <14>.

According to the present invention, it is possible to provide a novel photoelectric conversion film having a high external quantum efficiency with respect to light having a wavelength in the infrared region, a dispersion liquid, a photodetector element, and an image sensor.

### BRIEF DESCRIPTION OF THE DRAWINGS

FIG. 1 is a diagram illustrating an embodiment of a photodetector element.

### DESCRIPTION OF THE PREFERRED EMBODIMENTS

Hereinafter, the contents of the present invention will be described in detail. In the present specification, “to” is used to mean that numerical values described before and after “to” are included as a lower limit value and an upper limit value, respectively. In describing a group (an atomic group) in the present specification, in a case where a description of substitution and non-substitution is not provided, the description means the group includes a group (an atomic group) having a substituent as well as a group (an atomic group) having no substituent. For example, the “alkyl group” includes not only an alkyl group that does not have a substituent (an unsubstituted alkyl group) but also an alkyl group that has a substituent (a substituted alkyl group).

In the present invention, the “semiconductor” means a substance having a specific resistance value of 10⁻² Ω cm or more and 10⁸ Ω cm or less.

<Photoelectric Conversion Film>

A photoelectric conversion film according to the embodiment of the invention is characterized by containing a quantum dot of a compound semiconductor that contains an Ag element, at least one element selected from an Sb element or a Bi element, and at least one element selected from an Se element or a Te element.

The photoelectric conversion film according to the embodiment of the present invention has a high external quantum efficiency with respect to light having a wavelength in the infrared region. As a result, in a case of using the photoelectric conversion film according to the embodiment of the present invention as a photodetector element, it is possible to obtain a photodetector element having high sensitivity to light having a wavelength in the infrared region. In addition, since the photoelectric conversion film according to the embodiment of the present invention has a high external quantum efficiency with respect to light having a wavelength in the visible region, a photodetector element using the photoelectric conversion film according to the embodiment of the present invention can detect, at the same time, light having a wavelength in the infrared region and light having a wavelength in the visible region (preferably, light having a wavelength in the range of 400 to 700 nm).

The thickness of the photoelectric conversion film is not particularly limited; however, it is preferably 10 to 1,000 nm from the viewpoint of obtaining high electrical conductivity. The lower limit of the thickness is preferably 20 nm or more and more preferably 30 nm or more. The upper limit of the thickness is preferably 600 nm or less, more preferably 550 nm or less, still more preferably 500 nm or less, and particularly preferably 450 nm or less.

Hereinafter, the details of the photoelectric conversion film according to the embodiment of the present invention will be described.

The photoelectric conversion film according to the embodiment of the present invention contains quantum dots of a compound semiconductor that contains at least one element selected from an Ag (silver) element, an Sb (antimony) element, or a Bi (bismuth) element, and at least one element selected from an Se (selenium) element or a Te (tellurium) element. It is noted that the compound semiconductor is a semiconductor composed of two or more kinds of elements. As a result, in the present specification, “the compound semiconductor that contains an Ag element, at least one element selected from an Sb element or a Bi element, and at least one element selected from an Se element or a Te element” is a compound semiconductor that contains, as an element that constitutes the compound semiconductor, an Ag element, at least one element selected from an Sb element or a Bi element, and at least one element selected from an Se element or a Te element. In addition, in the present specification, the “semiconductor” means a substance having a specific resistance value of 10-2 Q cm or more and 10¹ Q cm or less.

The compound semiconductor, which is a quantum dot material constituting the quantum dot, is preferably a compound semiconductor containing an Ag element, a Bi element, and at least one element selected from an Se element or a Te element, and it is more preferably a compound semiconductor containing an Ag element, a Bi element, and Te element. According to this aspect, it is easy to obtain a photoelectric conversion film having a high external quantum efficiency with respect to light having a wavelength in the infrared region.

The compound semiconductor is preferably a compound semiconductor further containing an S (sulfur) element. According to this aspect, it is easy to obtain a photoelectric conversion film having a high external quantum efficiency with respect to light having a wavelength in the infrared region. Among the above, the compound semiconductor is preferably a compound semiconductor containing an Ag element, a Bi element, a Te element, and an S element (hereinafter, also referred to as an Ag—Bi—Te—S-based semiconductor). Further, in the Ag—Bi—Te—S-based semiconductor, a value obtained by dividing the number of Te elements by the total of the number of Te elements and the number of S elements ((the number of Te elements)/(the number of Te elements+the number of S elements)) is preferably 0.05 to 0.5. The lower limit thereof is preferably 0.1 or more, more preferably 0.15 or more, and still more preferably 0.2 or more. The upper limit thereof is preferably 0.45 or less and more preferably 0.4 or less. In the present specification, the kinds and the number of individual elements constituting the compound semiconductor can be measured by inductively coupled plasma (ICP) emission spectroscopy or energy dispersive X-ray spectroscopy.

The compound semiconductor is preferably a compound represented by Formula (1).

Agₙ₁X¹ₙ₂Y¹ₙ₃Sₙ₄ (1)

X¹ represents Sb or Bi, Y¹ represents Te or Se, n1 and n2 each independently represent a number of more than 0 and 2 or less, n3 represents a number of more than 0 and less than 4, and n4 represents a number of 0 or more and 4 or less.

X¹ is preferably Bi.

Y¹ is preferably Te.

The value of n1/n2 is preferably 0.2 to 3.0. The lower limit thereof is preferably 0.3 or more, more preferably 0.5 or more, and still more preferably 0.6 or more. The upper limit thereof is preferably 2.5 or less, more preferably 2.0 or less, and still more preferably 1.8 or less. The value of (n3+n4)/n2 is preferably 1.5 to 3.0. The lower limit thereof is preferably 1.6 or more, more preferably 1.8 or more, and still more preferably 1.9 or more. The upper limit thereof is preferably 2.5 or less, more preferably 2.4 or less, and still more preferably 2.2 or less. The value of n3/(n3+n4) is preferably 0.05 to 0.5. The lower limit thereof is preferably 0.1 or more, more preferably 0.15 or more, and still more preferably 0.2 or more. The upper limit thereof is preferably 0.45 or less and more preferably 0.4 or less. The value of n3/(n3+n4) may be 1 (that is, n4 may be zero).

The crystal structure of the compound semiconductor is not particularly limited. Various crystal structures can be adopted depending on the kind of the element constituting the compound semiconductor and the composition ratio of the element. However, due to the reason that it is easy to properly control a band gap as a semiconductor and it is easy to realize high crystallinity, a crystal structure of a cubic system or hexagonal system is preferable. In the present specification, the crystal structure of the compound semiconductor can be measured by an X-ray diffraction method or an electron beam diffraction method.

The band gap of the quantum dot of the compound semiconductor is preferably 1.2 eV or less and more preferably 1.0 eV or less. The lower limit value of the band gap of the quantum dot of the compound semiconductor is not particularly limited; however, it is preferably 0.3 eV or more and more preferably 0.5 eV or more.

The average particle diameter of the quantum dots of the compound semiconductor is preferably 3 to 20 nm. The lower limit value of the average particle diameter of the quantum dots of the compound semiconductor is preferably 4 nm or more and more preferably 5 nm or more. The upper limit value of the average particle diameter of the quantum dots of the compound semiconductor is preferably 15 nm or less and more preferably 10 nm or less. In a case where the average particle diameter of the quantum dots of the compound semiconductor is in the above range, it is easy to obtain a photoelectric conversion film having a high external quantum efficiency with respect to light having a wavelength in the infrared region. It is noted that in the present specification, the value of the average particle diameter of the quantum dots is an average value of the particle diameters of ten quantum dots which are randomly selected. A transmission electron microscope may be used for measuring the particle diameter of the quantum dots.

It is preferable that the photoelectric conversion film according to the embodiment of the present invention contains a ligand that is coordinated to the quantum dot of the compound semiconductor. Examples of the ligand include a ligand containing a halogen atom and a polydentate ligand containing two or more coordination moieties. The photoelectric conversion film may contain only one kind of ligand or may contain two or more kinds of ligands. Among the above, the photoelectric conversion film preferably contains a ligand containing a halogen atom and a polydentate ligand. In a case where a ligand containing a halogen atom is used, the surface coverage of the quantum dot by the ligand can be easily increased, and as a result, higher external quantum efficiency can be obtained. In a case where a polydentate ligand is used, the polydentate ligand is easily subjected to chelate coordination to the quantum dot, and the peeling of the ligand from the quantum dot can be suppressed more effectively, whereby excellent durability is obtained. Furthermore, in a case of being subjected to chelate coordination, steric hindrance between quantum dots can be suppressed, and high electrical conductivity is easily obtained, whereby high external quantum efficiency is obtained. In addition, in a case where a ligand containing a halogen atom and a polydentate ligand are used in combination, a higher external quantum efficiency is easily obtained. As described above, the polydentate ligand is presumed to be subjected to chelate coordination to the quantum dot. Furthermore, in a case where a ligand containing a halogen atom is further contained as the ligand that is coordinated to the quantum dot, it is presumed that the ligand containing a halogen atom is coordinated in the gap where the polydentate ligand is not coordinated, and thus it is presumed that the surface defects of the quantum dot can be further reduced. As a result, it is presumed that the external quantum efficiency can be further improved.

First, the ligand containing a halogen atom will be described. Examples of the halogen atom contained in the ligand include a fluorine atom, a chlorine atom, a bromine atom, and an iodine atom, and an iodine atom is preferable from the viewpoint of coordinating power.

The ligand containing a halogen atom may be an organic halide or may be an inorganic halide. Among the above, an inorganic halide is preferable due to the reason that it is easily coordinated to both the cation site and the anion site of the quantum dot. In addition, the inorganic halide is preferably a compound containing a metal element selected from a Zn (zinc) atom, an In (indium) atom, and a Cd (cadmium) atom, and it is more preferably a compound containing a Zn atom. The inorganic halide is preferably a salt of a metal atom and a halogen atom due to the reason that the salt is easily ionized and easily coordinated to the quantum dot.

Specific examples of the ligand containing a halogen atom include zinc iodide, zinc bromide, zinc chloride, indium iodide, indium bromide, indium chloride, cadmium iodide, cadmium bromide, and cadmium chloride, gallium iodide, gallium bromide, gallium chloride, tetrabutylammonium iodide, and tetramethylammonium iodide, and zinc iodide is particularly preferable.

It is noted that in the ligand containing a halogen atom, the halogen ion may be dissociated from the ligand described above, and the halogen ion may be coordinated on the surface of the quantum dot. In addition, a portion of the ligand other than the halogen atom described above may also be coordinated on the surface of the quantum dot. To give a description with a specific example, in the case of zinc iodide, zinc iodide may be coordinated on the surface of the quantum dot, or the iodine ion or the zinc ion may be coordinated on the surface of the quantum dot.

Next, the polydentate ligand will be described. Examples of the coordination moiety contained in the polydentate ligand include a thiol group, an amino group, a hydroxy group, a carboxy group, a sulfo group, a phospho group, and a phosphonate group.

Examples of the polydentate ligand include a ligand represented by any of Formulae (A) to (C).

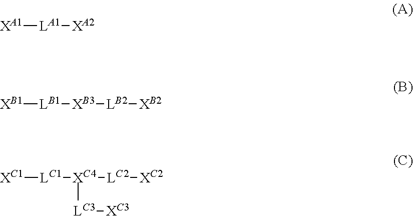

In Formula (A), X^{A1}and X^{A2} each independently represent a thiol group, an amino group, a hydroxy group, a carboxy group, a sulfo group, a phospho group, or a phosphonate group.

L^{A1} represents a hydrocarbon group.

In Formula (B), X^{B1} and X^{B2} each independently represent a thiol group, an amino group, a hydroxy group, a carboxy group, a sulfo group, a phospho group, or a phosphonate group.

X^{B3} represents S, O, or NH.

L^{B1}and L^{B2} each independently represent a hydrocarbon group.

In Formula (C), X^{C}i to X^{C3} each independently represent a thiol group, an amino group, a hydroxy group, a carboxy group, a sulfo group, a phospho group, or a phosphonate group.

X^{C4} represents N.

L^{C1} to L^{C3} each independently represent a hydrocarbon group.

The amino group represented by X^{A1}, X^{A2}, X^{B1}, X^{B2}, X^{C1}, X^{C2}, or X^{C3} is not limited to —NH₂ and includes a substituted amino group and a cyclic amino group as well. Examples of the substituted amino group include a monoalkylamino group, a dialkylamino group, a monoarylamino group, a diarylamino group, and an alkylarylamino group. The amino group represented by these groups is preferably —NH₂, a monoalkylamino group, or a dialkylamino group, and more preferably —NH₂.

The hydrocarbon group represented by L^{A1} , L^{B1}, L^{B2}, L^{C1}, L^{C2}, or L^{C3} is preferably an aliphatic hydrocarbon group. The aliphatic hydrocarbon group may be a saturated aliphatic hydrocarbon group or may be an unsaturated aliphatic hydrocarbon group. The hydrocarbon group preferably has 1 to 20 carbon atoms. The upper limit of the number of carbon atoms is preferably 10 or less, more preferably 6 or less, and still more preferably 3 or less. Specific examples of the hydrocarbon group include an alkylene group, an alkenylene group, and an alkynylene group.

Examples of the alkylene group include a linear alkylene group, a branched alkylene group, and a cyclic alkylene group. A linear alkylene group or a branched alkylene group is preferable, and a linear alkylene group is more preferable. Examples of the alkenylene group include a linear alkenylene group, a branched alkenylene group, and a cyclic alkenylene group. A linear alkenylene group or a branched alkenylene group is preferable, and a linear alkenylene group is more preferable. Examples of the alkynylene group include a linear alkynylene group and a branched alkynylene group, and a linear alkynylene group is preferable. The alkylene group, the alkenylene group, and the alkynylene group may further have a substituent. The substituent is preferably a group having 1 or more and 10 or less of atoms. Preferred specific examples of the group having 1 or more and 10 or less of atoms include an alkyl group having 1 to 3 carbon atoms [a methyl group, an ethyl group, a propyl group, or an isopropyl group], an alkenyl group having 2 or 3 carbon atoms [an ethenyl group or a propenyl group], an alkynyl group having 2 to 4 carbon atoms [an ethynyl group, a propynyl group, or the like], a cyclopropyl group, an alkoxy group having 1 or 2 carbon atoms [a methoxy group or an ethoxy group], an acyl group having 2 or 3 carbon atoms [an acetyl group or a propionyl group], an alkoxycarbonyl group having 2 or 3 carbon atoms [a methoxycarbonyl group or an ethoxycarbonyl group], an acyloxy group having 2 carbon atoms [an acetyloxy group], an acylamino group having 2 carbon atoms [an acetylamino group], a hydroxyalkyl group having 1 to 3 carbon atoms [a hydroxymethyl group, a hydroxyethyl group, or a hydroxypropyl group], an aldehyde group, a hydroxy group, a carboxy group, a sulfo group, a phospho group, a carbamoyl group, a cyano group, an isocyanate group, a thiol group, a nitro group, a nitroxy group, an isothiocyanate group, a cyanate group, a thiocyanate group, an acetoxy group, an acetamide group, a formyl group, a formyloxy group, a formamide group, a sulfamino group, a sulfino group, a sulfamoyl group, a phosphono group, an acetyl group, a halogen atom, and an alkali metal atom.

In Formula (A), X^{A1} and X^{A2} are separated by L^{A1} preferably by 1 to 10 atoms, more preferably separated by 1 to 6 atoms, still more preferably separated by 1 to 4 atoms, even still more preferably separated by 1 to 3 atoms separated, and particularly preferably separated by 1 or 2 atoms.

In Formula (B), X^{B1} and X^{B3} are separated by L^{B1} preferably by 1 to 10 atoms, more preferably separated by 1 to 6 atoms, still more preferably separated by 1 to 4 atoms, even still more preferably separated by 1 to 3 atoms separated, and particularly preferably separated by 1 or 2 atoms. In addition, X^{B2} and X^{B3} are separated by L^{B2} preferably by 1 to 10 atoms, more preferably separated by 1 to 6 atoms, still more preferably separated by 1 to 4 atoms, even still more preferably separated by 1 to 3 atoms separated, and particularly preferably separated by 1 or 2 atoms.

In Formula (C), X^{C1} and X^{C4} are separated by L^{C1} preferably by 1 to 10 atoms, more preferably separated by 1 to 6 atoms, still more preferably separated by 1 to 4 atoms, even still more preferably separated by 1 to 3 atoms separated, and particularly preferably separated by 1 or 2 atoms. In addition, X^{C2} and X^{C4} are separated by L^{C2} preferably by 1 to 10 atoms, more preferably separated by 1 to 6 atoms, still more preferably separated by 1 to 4 atoms, even still more preferably separated by 1 to 3 atoms separated, and particularly preferably separated by 1 or 2 atoms. In addition, X^{C3} and X^{C4} are separated by L^{C3} preferably by 1 to 10 atoms, more preferably separated by 1 to 6 atoms, still more preferably separated by 1 to 4 atoms, even still more preferably separated by 1 to 3 atoms separated, and particularly preferably separated by 1 or 2 atoms.

It is noted that the description that X^{A1} and X^{A2} are separated by L^{A1} by 1 to 10 atoms means that the number of atoms constituting a molecular chain having the shortest distance, connecting X^{A1} and X^{A2}, is 1 to 10 atoms. For example, in a case of Formula (A1), X^{A1} and X^{A2}are separated by two atoms, and in cases of Formulae (A2) and (A3), X^{A1} and X^{A2} are separated by 3 atoms. The numbers added to the following structural formulae represent the arrangement order of atoms constituting a molecular chain having the shortest distance, connecting X^{A1} and X^{A2}.

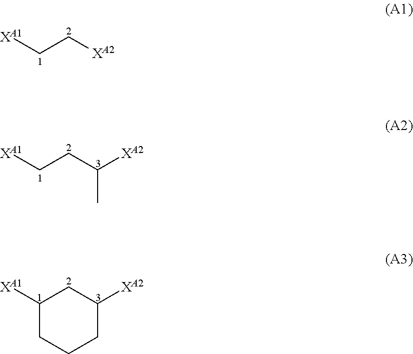

To give a description with a specific compound, 3-mercaptopropionic acid is a compound (a compound having the following structure) having a structure in which a portion corresponding to X^{A1} is a carboxy group, a portion corresponding to X^{A2} is a thiol group, and a portion corresponding to L^{A1} is an ethylene group. In 3-mercaptopropionic acid, X^{A1} (the carboxy group) and X^{A2} (the thiol group) are separated by L^{A1} (the ethylene group) by two atoms.

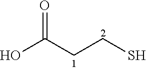

The same applies to the meanings that X^{B1} and X^{B3} are separated by L^{B1} by 1 to 10 atoms, X^{B2} and X^{B3} are separated by L^{B2} by 1 to 10 atoms, X^{C1} and X^{C4} are separated by L^{C1} by 1 to 10 atoms, X^{C2} and X^{C4} are separated by L^{C2} by 1 to 10 atoms, and X^{C3} and X^{C4} are separated by L^{C3}by 1 to 10 atoms.

Specific examples of the polydentate ligand include 3-mercaptopropionic acid, thioglycolic acid, 2-aminoethanol, 2-aminoethanethiol, 2-mercaptoethanol, glycolic acid, ethylene glycol, ethylenediamine, aminosulfonic acid, glycine, aminomethyl phosphoric acid, guanidine, diethylenetriamine, tris(2-aminoethyl)amine, 4-mercaptobutanoic acid, 3-aminopropanol, 3-mercaptopropanol, N-(3-aminopropyl)-1,3-propanediamine, 3-(bis(3-aminopropyl)amino)propane-1-ol, 1-thioglycerol, dimercaprol, 1-mercapto-2-butanol, 1-mercapto-2-pentanol, 3-mercapto-1-propanol, 2,3-dimercapto-1-propanol, diethanolamine, 2-(2-aminoethyl)aminoethanol, dimethylenetriamine, 1,1-oxybismethylamine, 1,1-thiobismethylamine, 2-[(2-aminoethyl)amino]ethanethiol, bis(2-mercaptoethyl)amine, 2-aminoethane-1-thiol, 1-amino-2-butanol, 1-amino-2-pentanol, L-cysteine, D-cysteine, 3-amino-i-propanol, L-homoserine, D-homoserine, aminohydroxyacetic acid, L-lactic acid, D-lactic acid, L-malic acid, D-malic acid, glyceric acid, 2-hydroxybutyric acid, L-tartaric acid, D-tartaric acid, tartronic acid, and derivatives thereof. Due to the reason that a semiconductor film has a low dark current and a high external quantum efficiency, the polydentate ligand is preferably thioglycolic acid, 2-aminoethanol, 2-aminoethanethiol, 2-mercaptoethanol, glycolic acid, diethylenetriamine, tris(2-aminoethyl)amine, 1-thioglycerol, dimercaprol, ethylenediamine, ethylene glycol, aminosulfonic acid, glycine, (aminomethyl)phosphonic acid, guanidine, diethanolamine, 2-(2-aminoethyl)aminoethanol, homoserine, cysteine, thiomalic acid, malic acid, or tartaric acid, more preferably thioglycolic acid, 2-aminoethanol, 2-mercaptoethanol, or 2-aminoethanethiol, and still more preferably thioglycolic acid.

<Dispersion Liquid>

The dispersion liquid according to the embodiment of the present invention is a dispersion liquid for forming a photoelectric conversion film and contains a quantum dot of a compound semiconductor that contains an Ag element, at least one element selected from an Sb element or a Bi element, and at least one element selected from an Se element or a Te element; a ligand that is coordinated to the quantum dot; and a solvent.

The details of the quantum dot are as described above, and the same applies to the preferred aspect thereof. The content of the quantum dot in the dispersion liquid is preferably 1 to 500 mg/mL, more preferably 10 to 200 mg/mL, and still more preferably 20 to 100 mg/mL.

The ligand contained in the quantum dot dispersion liquid acts as a ligand that is coordinated to the quantum dot and has a molecular structure that easily causes steric hindrance, and thus it is preferable that the ligand also serves as a dispersing agent that disperses quantum dots in the solvent.

From the viewpoint of improving the dispersibility of quantum dots, the ligand is preferably a ligand having at least 6 or more carbon atoms in the main chain and is more preferably a ligand having 10 or more carbon atoms in the main chain. The ligand may be any one of a saturated compound or an unsaturated compound. Specific examples of the ligand include decanoic acid, lauric acid, myristic acid, palmitic acid, stearic acid, behenic acid, oleic acid, erucic acid, oleylamine, stearylamine, 1-aminodecane, dodecylamine, aniline, dodecanethiol, 1,2-hexadecanethiol, tributylphosphine, trihexylphosphine, trioctylphosphine, tributylphosphine oxide, trioctylphosphine oxide, and cetrimonium bromide, where at least one selected from oleic acid, oleylamine, dodecanethiol, or trioctylphosphine is preferable.

The content of the ligand in the dispersion liquid is preferably 0.1 mmol/L to 500 mmol/L and more preferably 0.5 mmol/L to 100 mmol/L with respect to the total volume of the dispersion liquid.

The solvent contained in the dispersion liquid is not particularly limited; however, it is preferably a solvent that is difficult to dissolve the quantum dots but is easy to dissolve the ligand. The solvent is preferably an organic solvent. Specific examples thereof include alkanes (n-hexane, n-octane, and the like), alkenes (octadecene and the like), benzene, and toluene. The solvent contained in the dispersion liquid may be only one kind or may be a mixed solvent in which two or more kinds are mixed.

The content of the solvent in the dispersion liquid is preferably 50% to 99% by mass, more preferably 70% to 99% by mass, and still more preferably 90% to 98% by mass.

The dispersion liquid according to the embodiment of the present invention may further contain other components as long as the effects of the present invention are not impaired.

<Manufacturing Method for Photoelectric Conversion Film>

The photoelectric conversion film according to the embodiment of the present invention can be formed by undergoing a step of applying, onto a substrate, a dispersion liquid containing a quantum dot of a compound semiconductor that contains an Ag element, at least one element selected from an Sb element or a Bi element, and at least one element selected from an Se element or a Te element, a ligand that is coordinated to the quantum dot, and a solvent, and forming a film of the aggregate of quantum dots (a quantum dot aggregate forming step).

The shape, structure, size, and the like of the substrate onto which the dispersion liquid is applied are not particularly limited, and the substrate can be appropriately selected depending on the intended purpose. The structure of the substrate may be a monolayer structure or a laminated structure. As the substrate, for example, a substrate composed of an inorganic material such as silicon, glass, or yttria-stabilized zirconia (YSZ), a resin, a resin composite material, or the like can be used. In addition, an electrode, an insulating film, or the like may be formed on the substrate. In that case, the quantum dot dispersion liquid is also applied onto the electrode or the insulating film on the substrate.

The method of applying a quantum dot dispersion liquid onto a substrate is not particularly limited. Examples thereof include coating methods such as a spin coating method, a dipping method, an ink jet method, a dispenser method, a screen printing method, a relief printing method, an intaglio printing method, and a spray coating method.

The film thickness of the film of aggregates of the quantum dots, formed by the quantum dot aggregate forming step, is preferably 3 nm or more, more preferably 10 nm or more, and still more preferably 20 nm or more. The upper limit thereof is preferably 200 nm or less, more preferably 150 nm or less, and still more preferably 100 nm or less.

After forming a film of the aggregate of quantum dots, a ligand exchange step may be further carried out to exchange the ligand coordinated to the quantum dot with another ligand. In the ligand exchange step, a ligand solution containing a ligand (hereinafter, also referred to as a ligand A) different from the ligand contained in the above-described dispersion liquid and containing a solvent is applied onto the film of the aggregate of quantum dots, the aggregate being formed by the quantum dot aggregate forming step, to exchange the ligand coordinated to the quantum dot with the ligand A contained in the ligand solution. In addition, the quantum dot aggregate forming step and the ligand exchange step may be alternately repeated a plurality of times.

Examples of the ligand A include a ligand containing a halogen atom and a polydentate ligand containing two or more coordination moieties. Examples of the details thereof include those described in the section of the photoelectric conversion film described above, and the same applies to the preferred range thereof.

The ligand solution that is used in the ligand exchange step may contain only one kind of the ligand A or may contain two or more kinds thereof. In addition, two or more kinds of ligand solutions may be used.

The solvent contained in the ligand solution is preferably selected appropriately according to the kind of the ligand contained in each ligand solution, and it is preferably a solvent that easily dissolves each ligand. In addition, the solvent contained in the ligand solution is preferably an organic solvent having a high dielectric constant. Specific examples thereof include ethanol, acetone, methanol, acetonitrile, dimethylformamide, dimethyl sulfoxide, butanol, and propanol. In addition, the solvent contained in the ligand solution is preferably a solvent that does not easily remain in the formed photoelectric conversion film. From the viewpoints of easy drying and easy removal by washing, a low boiling point alcohol, a ketone, or a nitrile is preferable, and methanol, ethanol, acetone, or acetonitrile is more preferable. The solvent contained in the ligand solution is preferably one that does not mix with the solvent contained in the quantum dot dispersion liquid. Regarding the preferred solvent combination, in a case where the solvent contained in the quantum dot dispersion liquid is an alkane such as hexane or octane or toluene, it is preferable to use a polar solvent such as methanol or acetone as the solvent contained in the ligand solution.

The method for applying the ligand solution onto a film of the aggregate of quantum dots is the same as the method for applying the quantum dot dispersion liquid onto the substrate, and the same applies to the preferred aspect thereof.

A step (a rinsing step) of bringing a rinsing liquid into contact with a film after the ligand exchange step to rinse the film may be carried out. In a case where the rinsing step is carried out, it is possible to remove the excess ligand contained in the film and the ligand released from the quantum dots. In addition, it is possible to remove the remaining solvent and other impurities. The rinsing liquid is preferably an aprotic solvent due to the reason that it is easier to effectively remove excess ligands contained in the film and ligands released from the quantum dots, and it is easy to keep the film surface shape uniform by rearranging the surface of the quantum dots. Specific examples of the aprotic solvent include acetonitrile, acetone, methyl ethyl ketone, methyl isobutyl ketone, cyclopentanone, diethyl ether, tetrahydrofuran, cyclopentyl methyl ether, dioxane, ethyl acetate, butyl acetate, propylene glycol monomethyl ether acetate, hexane, octane, cyclohexane, benzene, toluene, chloroform, carbon tetrachloride, and dimethylformamide, where acetonitrile or tetrahydrofuran is preferable, and acetonitrile is more preferable.

In addition, the rinsing step may be carried out a plurality of times by using two or more kinds of rinsing liquids differing in polarity (relative permittivity). For example, it is preferable that, first, a rinsing liquid (also referred to as a first rinsing liquid) having a high relative permittivity is used to carry out rinsing, and then a rinsing liquid (also referred to as a second rinsing liquid) having a relative permittivity lower than that of the first rinsing liquid is used to carry out rinsing. In a case of rinsing in this way, it is possible to first remove the excess component of the ligand A used in the ligand exchange, and then remove the released ligand component (the component that has been originally coordinated to the particles) generated in the ligand exchange process, and it is possible to more efficiently remove both the excess or the released ligand component.

The relative permittivity of the first rinsing liquid is preferably 15 to 50, more preferably 20 to 45, and still more preferably 25 to 40. The relative permittivity of the second rinsing liquid is preferably 1 to 15, more preferably 1 to 10, and still more preferably 1 to 5.

The manufacturing method for a photoelectric conversion film may include a drying step. In a case of carrying out the drying step, it is possible to remove the solvent remaining on the photoelectric conversion film. The drying time is preferably 1 to 100 hours, more preferably ito 50 hours, and still more preferably 5 to 30 hours. The drying temperature is preferably 10° C. to 100° C., more preferably 20° C. to 90° C., and still more preferably 20° C. to 50° C.

<Photodetector Element>

The photodetector element according to the embodiment of the present invention includes the above-described photoelectric conversion film according to the embodiment of the present invention.

The thickness of the photoelectric conversion film according to the embodiment of the present invention in the photodetector element is preferably 10 to 1,000 nm. The lower limit of the thickness is preferably 20 nm or more and more preferably 30 nm or more. The upper limit of the thickness is preferably 600 nm or less, more preferably 550 nm or less, still more preferably 500 nm or less, and particularly preferably 450 nm or less.

Examples of the type of photodetector element include a photoconductor-type photodetector element and a photodiode-type photodetector element. Among the above, a photodiode-type photodetector element is preferable due to the reason that a high signal-to-noise ratio (SN ratio) is easily obtained.

In addition, since the photoelectric conversion film according to the embodiment of the present invention has excellent sensitivity to the light having a wavelength in the infrared region, the photodetector element according to the embodiment of the present invention is preferably used as a photodetector element that detects light having a wavelength in the infrared region. That is, the photodetector element according to the embodiment of the present invention is preferably used as an infrared photodetector element.

The light having a wavelength in the infrared region is preferably light having a wavelength of more than 700 nm, more preferably light having a wavelength of 800 nm or more, still more preferably light having a wavelength of 900 nm or more, and even still preferably light having a wavelength of 1,000 nm or more. In addition, the light having a wavelength in the infrared region is preferably light having a wavelength of 2,000 nm or less, more preferably light having a wavelength of 1,800 nm or less, and still more preferably light having a wavelength of 1,600 nm or less.

The photodetector element may be a photodetector element that simultaneously detects light having a wavelength in the infrared region and light having a wavelength in the visible region (preferably light having a wavelength in a range of 400 to 700 nm).

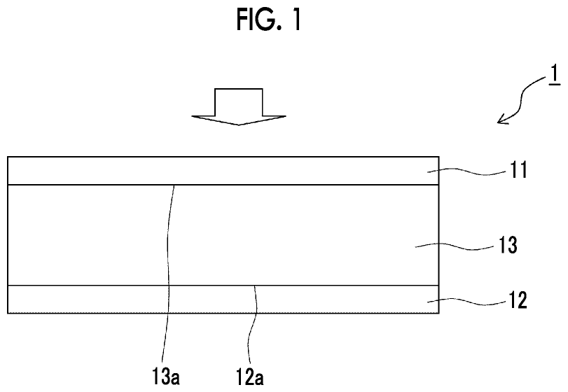

FIG. 1 illustrates an embodiment of a photodiode-type photodetector element. It is noted that an arrow in the figure represents the incidence ray on the photodetector element. A photodetector element 1 illustrated in FIG. 1 includes a lower electrode 12, an upper electrode 11 opposite to the lower electrode 12, and a photoelectric conversion film 13 provided between the lower electrode 12 and the upper electrode 11. The photodetector element 1 illustrated in FIG. 1 is used by causing light to be incident from above the upper electrode 11.

The photoelectric conversion film 13 is composed of the above-described photoelectric conversion film according to the embodiment of the present invention.

The refractive index of the photoelectric conversion film 13 with respect to light having a target wavelength to be detected by the photodetector element can be set to 1.5 to 5.0.

The thickness of the photoelectric conversion film 13 is preferably 10 to 1,000 nm. The lower limit of the thickness is preferably 20 nm or more and more preferably 30 nm or more. The upper limit of the thickness is preferably 600 nm or less, more preferably 550 nm or less, still more preferably 500 nm or less, and particularly preferably 450 nm or less.

The wavelength λ of the target light to be detected by the photodetector element and an optical path length L^{λ} of the light having the wavelength X from a surface 12a of the lower electrode 12 on a side of the photoelectric conversion film 13 to a surface 13a of the photoelectric conversion film 13 on a side of the upper electrode preferably satisfy the relationship of Expression (1-1), and more preferably satisfy the relationship of Expression (1-2). In a case where the wavelength X and the optical path length L′ satisfy such a relationship, in the photoelectric conversion film 13, it is possible to arrange phases of the light (the incidence ray) incident from the side of the upper electrode 11 and phases of the light (the reflected light) reflected on the surface of the lower electrode 12, and as a result, the light is intensified by the optical interference effect, whereby it is possible to obtain a higher external quantum efficiency.

0.05+m/2≤L^{λ}/λ≤0.35+m/2 (1-1)

0.10+m/2<L^{λ}/λ≤0.30+m/2 (1-2)

In the above expressions, X is the wavelength of the target light to be detected by the photodetector element, L^{λ}is the optical path length of light having a wavelength X from a surface 12a of the lower electrode 12 on a side of the photoelectric conversion film 13 to a surface 13a of the photoelectric conversion film 13 on a side of the upper electrode, and m is an integer of 0 or more. [0080] m is preferably an integer of 0 to 4, more preferably an integer of 0 to 3, still more preferably an integer of 0 to 2, and particularly preferably 0 or 1.

Here, the optical path length means the product obtained by multiplying the physical thickness of a substance through which light transmits by the refractive index. To give a description with the photoelectric conversion film 13 as an example, in a case where the thickness of the photoelectric conversion film is denoted by d¹ and the refractive index of the photoelectric conversion film with respect to the wavelength λ¹ is denoted by N¹, the optical path length of the light having a wavelength X1 and transmitting through the photoelectric conversion film 13 is N¹ ×d¹. In a case where the photoelectric conversion film 13 is composed of two or more laminated films or in a case where an interlayer described later is present between the photoelectric conversion film 13 and the lower electrode 12, the integrated value of the optical path length of each layer is the optical path length L.

The upper electrode 11 is preferably a transparent electrode formed of a conductive material that is substantially transparent with respect to the wavelength of the target light to be detected by the photodetector element. It is noted that in the present invention, the description of “substantially transparent” means that the light transmittance is 50% or more, preferably 60% or more, and particularly preferably 80% or more. Examples of the material of the upper electrode 11 include a conductive metal oxide. Specific examples thereof include tin oxide, zinc oxide, indium oxide, indium tungsten oxide, indium zinc oxide (IZO), indium tin oxide (ITO), and a fluorine-doped tin oxide (FTO).

The film thickness of the upper electrode 11 is not particularly limited, and it is preferably 0.01 to 100 m, more preferably 0.01 to 10 m, and particularly preferably 0.01 to 1 m. It is noted that in the present invention, the film thickness of each layer can be measured by observing the cross section of the photodetector element 1 using a scanning electron microscope (SEM) or the like.

Examples of the material that forms the lower electrode 12 include a metal such as platinum, gold, nickel, copper, silver, indium, ruthenium, palladium, rhodium, iridium, osmium, or aluminum, the above-described conductive metal oxide, a carbon material, and a conductive polymer. The carbon material may be any material having conductivity, and examples thereof include fullerene, a carbon nanotube, graphite, and graphene.

The film thickness of the lower electrode 12 is not particularly limited, and it is preferably 0.01 to 100 m, more preferably 0.01 to 10 m, and particularly preferably 0.01 to 1 μm.

Although not illustrated in the drawing, a transparent substrate may be arranged on the surface of the upper electrode 11 on the light incident side (the surface opposite to the side of the photoelectric conversion film 13). Examples of the kind of transparent substrate include a glass substrate, a resin substrate, and a ceramic substrate.

In addition, although not illustrated in the drawing, an interlayer may be provided between the photoelectric conversion film 13 and the lower electrode 12 and/or between the photoelectric conversion film 13 and the upper electrode 11. Examples of the interlayer include a blocking layer, an electron transport layer, and a hole transport layer. Examples of the preferred aspect thereof include an aspect in which the hole transport layer is provided at any one of a gap between the photoelectric conversion film 13 and the lower electrode 12 or a gap between the photoelectric conversion film 13 and the upper electrode 11. It is more preferable that the electron transport layer is provided at any one of a gap between the photoelectric conversion film 13 and the lower electrode 12 or a gap between the photoelectric conversion film 13 and the upper electrode 11, and the hole transport layer is provided at the other gap. The hole transport layer and the electron transport layer may be a single-layer film or a laminated film having two or more layers.

The blocking layer is a layer having a function of preventing a reverse current. The blocking layer is also called a short circuit prevention layer. Examples of the material that forms the blocking layer include silicon oxide, magnesium oxide, aluminum oxide, calcium carbonate, cesium carbonate, polyvinyl alcohol, polyurethane, titanium oxide, tin oxide, zinc oxide, niobium oxide, and tungsten oxide. The blocking layer may be a single-layer film or a laminated film having two or more layers.

The electron transport layer is a layer having a function of transporting electrons generated in the photoelectric conversion film 13 to the upper electrode 11 or the lower electrode 12. The electron transport layer is also called a hole block layer. The electron transport layer is formed of an electron transport material capable of exhibiting this function. Examples of the electron transport material include a fullerene compound such as [6,6]-phenyl-C61-butyric acid methyl ester (PC₆₁BM), a perylene compound such as perylenetetracarboxylic diimide, tetracyanoquinodimethane, titanium oxide, tin oxide, zinc oxide, indium oxide, indium tungsten oxide, indium zinc oxide, indium tin oxide, and fluorine-doped tin oxide. The electron transport layer may be a single-layer film or a laminated film having two or more layers.

The hole transport layer is a layer having a function of transporting holes generated in the photoelectric conversion film 13 to the upper electrode 11 or the lower electrode 12. The hole transport layer is also called an electron block layer. The hole transport layer is formed of a hole transport material capable of exhibiting this function. Examples thereof include PTB7 (poly({4,8-bis[(2-ethylhexyl)oxy]benzo[1,2-b:4,5-b′]dithiophen-2,6-diyl}{3-fluoro-2-[(2-ethyl hexyl)carbonyl]thieno[3,4-b]thiophendiyl})), PEDOT:PSS (poly (3,4-ethylenedioxythiophene):poly(4-styrenesulfonic acid)), and MoO₃. In addition, the organic hole transport material disclosed in paragraph Nos. 0209 to 0212 of JP2001-291534A can also be used. In addition, a quantum dot can also be used in the hole transport material. The average particle diameter of the quantum dots is preferably 0.5 to 100 nm. Examples of the quantum dot material include a) a IV Group semiconductor, b) a IV-IV Group, III-IV Group, or II-VI Group compound semiconductor, and c) a compound semiconductor consisting of a combination of at least three of a Group II element, a Group III element, a Group IV element, a Group V element, and a Group VI element. Specific examples thereof include semiconductors having a relatively narrow band gap, such as PbS, PbSe, PbTe, PbSeS, InN, InAs, Ge, InGaAs, CuInS, CuInSe, CuInGaSe, InSb, HgTe, HgCdTe, Ag₂S, Ag₂Se, Ag₂Te, SnS, SnSe, SnTe, Si, and InP. In addition, it is also possible to use, in the hole transport material, the compound semiconductor that contains an Ag element, at least one element selected from an Sb element or a Bi element, and at least one element selected from an Se element or a Te element, which is described in the section of the photoelectric conversion film described above. In addition, a ligand may be coordinated on the surface of the quantum dot. Examples of the ligand include the ligand described in the section of the photoelectric conversion film described above.

<Image Sensor>

The image sensor according to the embodiment of the present invention includes the above-described photodetector element according to the embodiment of the present invention. Since the photodetector element according to the embodiment of the present invention has excellent sensitivity to light having a wavelength in the infrared region, it can be particularly preferably used as an infrared image sensor.

The configuration of the image sensor is not particularly limited as long as it has the photodetector element according to the embodiment of the present invention and it is a configuration that functions as an image sensor.

The image sensor may include an infrared transmitting filter layer. The infrared transmitting filter layer preferably has a low light transmittance in the wavelength range of the visible region, more preferably has an average light transmittance of 10% or less, still more preferably 7.5% or less, and particularly preferably 5% or less in a wavelength range of 400 to 650 nm.

Examples of the infrared transmitting filter layer include those composed of a resin film containing a coloring material. Examples of the coloring material include a chromatic coloring material such as a red coloring material, a green coloring material, a blue coloring material, a yellow coloring material, a purple coloring material, and an orange coloring material, and a black coloring material. It is preferable that the coloring material contained in the infrared transmitting filter layer forms a black color with a combination of two or more kinds of chromatic coloring materials or a coloring material containing a black coloring material. Examples of the combination of the chromatic coloring material in a case of forming a black color by a combination of two or more kinds of chromatic coloring materials include the following aspects (C1) to (C7).
(C1) An aspect containing a red coloring material and a blue coloring material.
(C2) An aspect containing a red coloring material, a blue coloring material, and a yellow coloring material.
(C3) An aspect containing a red coloring material, a blue coloring material, a yellow coloring material, and a purple coloring material.
(C4) An aspect containing a red coloring material, a blue coloring material, a yellow coloring material, a purple coloring material, and a green coloring material.
(C5) An aspect containing a red coloring material, a blue coloring material, a yellow coloring material, and a green coloring material.
(C6) An aspect containing a red coloring material, a blue coloring material, and a green coloring material.
(C7) an aspect containing a yellow coloring material and a purple coloring material.

The chromatic coloring material may be a pigment or a dye. It may contain a pigment and a dye. The black coloring material is preferably an organic black coloring material. Examples of the organic black coloring material include a bisbenzofuranone compound, an azomethine compound, a perylene compound, and an azo compound.

The infrared transmitting filter layer may further contain an infrared absorber. In a case where the infrared absorber is contained in the infrared transmitting filter layer, the wavelength of the light to be transmitted can be shifted to the longer wavelength side. Examples of the infrared absorber include a pyrrolo pyrrole compound, a cyanine compound, a squarylium compound, a phthalocyanine compound, a naphthalocyanine compound, a quaterrylene compound, a merocyanine compound, a croconium compound, an oxonol compound, an iminium compound, a dithiol compound, a triarylmethane compound, a pyrromethene compound, an azomethine compound, an anthraquinone compound, a dibenzofuranone compound, a dithiolene metal complex, a metal oxide, and a metal boride.

The spectral characteristics of the infrared transmitting filter layer can be appropriately selected according to the use application of the image sensor. Examples of the filter layer include those that satisfy any one of the following spectral characteristics of (1) to (5).
(1): A filter layer in which the maximum value of the light transmittance in the film thickness direction in a wavelength range of 400 to 750 nm is 20% or less (preferably 15% or less and more preferably 10% or less), and the minimum value of the light transmittance in the film thickness direction in a wavelength range of 900 to 1,500 nm is 70% or more (preferably 75% or more and more preferably 80% or more).
(2): A filter layer in which the maximum value of the light transmittance in the film thickness direction in a wavelength range of 400 to 830 nm is 20% or less (preferably 15% or less and more preferably 10% or less), and the minimum value of the light transmittance in the film thickness direction in a wavelength range of 1,000 to 1,500 nm is 70% or more (preferably 75% or more and more preferably 80% or more).
(3): A filter layer in which the maximum value of the light transmittance in the film thickness direction in a wavelength range of 400 to 950 nm is 20% or less (preferably 15% or less and more preferably 10% or less), and the minimum value of the light transmittance in the film thickness direction in a wavelength range of 1,100 to 1,500 nm is 70% or more (preferably 75% or more and more preferably 80% or more).
(4): A filter layer in which the maximum value of the light transmittance in the film thickness direction in a wavelength range of 400 to 1,100 nm is 20% or less (preferably 15% or less and more preferably 10% or less), and the minimum value thereof in a wavelength range of 1,400 to 1,500 nm is 70% or more (preferably 75% or more and more preferably 80% or more).
(5): A filter layer in which the maximum value of the light transmittance in the film thickness direction in a wavelength range of 400 to 1,300 nm is 20% or less (preferably 15% or less and more preferably 10% or less), and the minimum value thereof in a wavelength range of 1,600 to 2,000 nm is 70% or more (preferably 75% or more and more preferably 80% or more).

Further, in the infrared transmitting filter, the film disclosed in JP2013-077009A, JP2014-130173A, JP2014-130338A, WO2015/166779A, WO2016/178346A, WO2016/190162A, WO2018/016232A, JP2016-177079A, JP2014-130332A, or WO2016/027798A can be used. As the infrared transmitting filter, two or more filters may be used in combination, or a dual bandpass filter that transmits through two or more specific wavelength ranges with one filter may be used.

The image sensor according to the embodiment of the present invention may include an infrared shielding filter for the intended purpose of improving various performances such as noise reduction. Specific examples of the infrared shielding filter include the filters disclosed in WO2016/186050A, WO2016/035695A, JP6248945B, WO2019/021767A, JP2017-067963A, and JP6506529B.

The image sensor according to the embodiment of the present invention may include a dielectric multi-layer film. Examples of the dielectric multi-layer film include those in which a plurality of layers of dielectric thin films having a high refractive index (high refractive index material layers) and dielectric thin films having a low refractive index (low refractive index material layers) are laminated alternately. The number of laminated layers of the dielectric thin film in the dielectric multi-layer film is not particularly limited; however, it is preferably 2 to 100 layers, more preferably 4 to 60 layers, and still more preferably 6 to 40 layers. The material that is used in forming the high refractive index material layer is preferably a material having a refractive index of 1.7 to 2.5. Specific examples thereof include Sb₂03, Sb₂S3, Bi₂O3, CeO2, CeF₃, HfO₂, La₂O₃, Nd₂03, Pr₆Ori, Sc203, SiO, Ta₂O₅, TiO₂, TlCl, Y₂03, ZnSe, ZnS, and ZrO2. The material that is used in forming the low refractive index material layer is preferably a material having a refractive index of 1.2 to 1.6. Specific examples thereof include A1₂O₃, BiF₃, CaF₂, LaF₃, PbCl₂, PbF₂, LiF, MgF2, MgO, NdF₃, SiO₂, Si₂O3, NaF, ThO₂, ThF₄, and Na₃AlF₆. The method for forming the dielectric multi-layer film is not particularly limited; however, examples thereof include ion plating, a vacuum deposition method using an ion beam or the like, a physical vapor deposition method (a PVD method) such as sputtering, and a chemical vapor deposition method (a CVD method). The thickness of each of the high refractive index material layer and the low refractive index material layer is preferably 0.1 X to 0.5 X in a case where the wavelength of the light to be blocked is X (nm). Specific examples of the usable dielectric multi-layer film include the films disclosed in JP2014-130344A and JP2018-010296A.

In the dielectric multi-layer film, the transmission wavelength range is preferably present in the infrared region (preferably a wavelength range having a wavelength of more than 700 nm, more preferably a wavelength range having a wavelength of more than 800 nm, and still more preferably a wavelength range having a wavelength of more than 900 nm). The maximum transmittance in the transmission wavelength range is preferably 70% or more, more preferably 80% or more, and still more preferably 90% or more. In addition, the maximum transmittance in the shielding wavelength range is preferably 20% or less, more preferably 10% or less, and still more preferably 5% or less. In addition, the average transmittance in the transmission wavelength range is preferably 60% or more, more preferably 70% or more, and still more preferably 80% or more. In addition, in a case where the wavelength at which the maximum transmittance is exhibited is denoted by a central wavelength Xti, the wavelength range of the transmission wavelength range is preferably “the central wavelength Xti+100 nm”, more preferably “the central wavelength λₜ₁±75 nm”, and still more preferably “the central wavelength λₜ₁+50 nm”.

The dielectric multi-layer film may have only one transmission wavelength range (preferably, a transmission wavelength range having a maximum transmittance of 90% or more) or may have a plurality of transmission wavelength ranges.

The image sensor according to the embodiment of the present invention may include a color separation filter layer. Examples of the color separation filter layer include a filter layer including colored pixels. Examples of the kind of colored pixel include a red pixel, a green pixel, a blue pixel, a yellow pixel, a cyan pixel, and a magenta pixel. The color separation filter layer may include colored pixels having two or more colors or having only one color. It can be appropriately selected according to the use application and the intended purpose. For example, the filter disclosed in WO2019/039172A can be used.

In addition, in a case where the color separation layer includes colored pixels having two or more colors, the colored pixels of the respective colors may be adjacent to each other, or a partition wall may be provided between the respective colored pixels. The material of the partition wall is not particularly limited. Examples thereof include an organic material such as a siloxane resin or a fluororesin, and an inorganic particle such as a silica particle. In addition, the partition wall may be composed of a metal such as tungsten or aluminum.

In a case where the image sensor according to the embodiment of the present invention includes an infrared transmitting filter layer and a color separation layer, it is preferable that the color separation layer is provided on an optical path different from the infrared transmitting filter layer. In addition, it is also preferable that the infrared transmitting filter layer and the color separation layer are arranged two-dimensionally. The description that the infrared transmitting filter layer and the color separation layer are two-dimensionally arranged means that at least parts of both are present on the same plane.

The image sensor according to the embodiment of the present invention may include an interlayer such as a planarizing layer, an underlying layer, or an intimate attachment layer, an anti-reflection film, and a lens. As the anti-reflection film, for example, a film produced from the composition disclosed in WO2019/017280A can be used. As the lens, for example, the structure disclosed in WO2018/092600A can be used.

The image sensor according to the embodiment of the present invention can be preferably used as an infrared image sensor. In addition, the image sensor according to the embodiment of the present invention can be preferably used as a sensor that senses light having a wavelength of 900 to 2,000 nm and can be more preferably used as a sensor that senses light having a wavelength of 900 to 1,600 nm.

### EXAMPLES

Hereinafter, the present invention will be described in detail with reference to Examples. Materials, amounts used, proportions, treatment details, treatment procedures, and the like shown in the following examples can be appropriately changed without departing from the gist of the present invention. Accordingly, a scope of the present invention is not limited to the following specific examples.

[Production of quantum dot dispersion liquid]

(Production Example 1)

20 ml of oleylamine, 1 mmol of silver nitrate, and 10 mL of octadecene were weighed out in a flask, and those were heated at 100° C. for 180 minutes under reduced pressure (several to several tens Pa). The temperature of the liquid in the flask was cooled to 30° C., and the inside of the flask was brought into a nitrogen flow state. Next, a solution obtained by dissolving 1 mmol of Bi[N(SiCH₃)2]₃ in 1 mL of toluene was added to the liquid in the flask. Next, the temperature of the liquid in the flask was raised to 100° C., and then a solution obtained by dissolving 2 mmol of Se in a mixed solution of 1 mL of oleylamine and 1 mL of dodecanethiol was added to the liquid in the flask. The temperature of the liquid in the flask was raised to 200° C., the liquid was maintained at this temperature for 15 minutes and then cooled to room temperature. Next, an excess amount of ethanol was added to the liquid in the flask, centrifugation was carried out at 10,000 rpm for 10 minutes to remove the supernatant, and then the precipitate was dispersed in toluene, thereby obtaining a dispersion liquid (concentration of quantum dots: 20 mg/mL) in which dodecanethiol and oleylamine were coordinated as ligands on the surface of quantum dots of an AgBiSe compound semiconductor in which the crystal structure was hexagonal and the atomic ratio estimated from the energy dispersive X-ray spectroscopy was Ag:Bi:Se=1.4:1.0:1.9 (a quantum dot dispersion liquid of Production Example 1). The band gap of the quantum dot was estimated from light absorption measurement in the visible to infrared region by using an ultraviolet-visible-near infrared spectrophotometer (V-670, manufactured by JASCO Corporation), and it was approximately 0.81 eV. The crystal structure of the compound semiconductor constituting the quantum dots was measured by an X-ray diffraction method. [0110] (Production Example 2) 20 ml of oleylamine, 1 mmol of silver nitrate, and 10 mL of octadecene were weighed out in a flask, and those were heated at 100° C. for 180 minutes under reduced pressure (several to several tens Pa). The temperature of the liquid in the flask was cooled to 30° C., and the inside of the flask was brought into a nitrogen flow state. Next, a solution obtained by dissolving 0.9 mmol of lithium triethylborohydride and 1 mmol of Sb[N(SiCH₃)2]₃ in 1 mL of toluene was added to the liquid in the flask. Subsequently, a solution obtained by dissolving 2.5 mmol of Se in a mixed solution of 1 mL of oleylamine and 1 mL of dodecanethiol was added to the liquid in the flask. The temperature of the liquid in the flask was raised to 180° C., the liquid was maintained at this temperature for 15 minutes and then cooled to room temperature. Next, an excess amount of ethanol was added to the liquid in the flask, centrifugation was carried out at 10,000 rpm for 10 minutes to remove the supernatant, and then the precipitate was dispersed in toluene, thereby obtaining a dispersion liquid (concentration of quantum dots: 20 mg/mL) in which dodecanethiol and oleylamine were coordinated as ligands on the surface of quantum dots of an AgSbSe compound semiconductor in which the crystal structure was cubic and the atomic ratio estimated from the energy dispersive X-ray spectroscopy was Ag:Sb:Se=1.5:1.0:1.9 (a quantum dot dispersion liquid of Production Example 2). The band gap of the quantum dot was estimated from light absorption measurement in the visible to infrared region by using an ultraviolet-visible-near infrared spectrophotometer (V-670, manufactured by JASCO Corporation), and it was approximately 0.76 eV

(Production Example 3)

1 mmol of bismuth acetate, 0.8 mmol of silver acetate, 5.4 mL of oleic acid, and 30 mL of octadecene were weighed out in a flask, and those were heated at 100° C. for 5 hours under reduced pressure (several to several tens Pa). Next, the inside of the flask was brought into a nitrogen flow state, and then a solution obtained by mixing 0.9 mmol of hexamethyl disilathiane and 0.1 mmol of bistrimethylsilyl telluride in 5 mL of octadecene was added to the liquid in the flask. Next, the temperature of the liquid in the flask was lowered to room temperature for cooling. Next, an excess amount of acetone was added to the solution in the flask, centrifugation was carried out at 10,000 rpm for 10 minutes to remove the supernatant, and then the precipitate was dispersed in toluene, thereby obtaining a dispersion liquid (concentration of quantum dots: 20 mg/mL) in which oleic acid was coordinated as ligands on the surface of quantum dots of an AgBiSTe compound semiconductor in which the crystal structure was cubic and the atomic ratio estimated from the energy dispersive X-ray spectroscopy was Ag:Bi:S:Te=1.4:1.0:1.8:0.2 (a quantum dot dispersion liquid of Production Example 3). The band gap of the quantum dot was estimated from light absorption measurement in the visible to infrared region by using an ultraviolet-visible-near infrared spectrophotometer (V-670, manufactured by JASCO Corporation), and it was approximately 0.95 eV

(Production Example 4) The adjustment was carried out according to the same method as in Production Example 3 except that in Production Example 3, the ratio between hexamethyl disilathiane and bistrimethylsilyl telluride was changed, thereby obtaining a dispersion liquid (concentration of quantum dots: 20 mg/mL) in which oleic acid was coordinated as ligands on the surface of quantum dots of an AgBiSTe compound semiconductor in which the crystal structure was cubic and the atomic ratio estimated from the energy dispersive X-ray spectroscopy was Ag:Bi:S:Te=1.5:1.0:1.6:0.4 (a quantum dot dispersion liquid of Production Example 4). The band gap of the quantum dot was estimated from light absorption measurement in the visible to infrared region by using an ultraviolet-visible-near infrared spectrophotometer (V-670, manufactured by JASCO Corporation), and it was approximately 0.91 eV

(Production Example 5)

The adjustment was carried out according to the same method as in Production Example 3 except that in Production Example 3, the ratio between hexamethyl disilathiane and bistrimethylsilyl telluride was changed, thereby obtaining a dispersion liquid (concentration of quantum dots: 20 mg/mL) in which oleic acid was coordinated as ligands on the surface of quantum dots of an AgBiSTe compound semiconductor in which the crystal structure was cubic and the atomic ratio estimated from the energy dispersive X-ray spectroscopy was Ag:Bi:S:Te=1.5:1.0:1.4:0.6 (a quantum dot dispersion liquid of Production Example 5). The band gap of the quantum dot was estimated from light absorption measurement in the visible to infrared region by using an ultraviolet-visible-near infrared spectrophotometer (V-670, manufactured by JASCO Corporation), and it was approximately 0.82 eV [0114] (Production Example 6) The adjustment was carried out according to the same method as in Production Example 3 except that in Production Example 3, the ratio between hexamethyl disilathiane and bistrimethylsilyl telluride was changed, thereby obtaining a dispersion liquid (concentration of quantum dots: 20 mg/mL) in which oleic acid was coordinated as ligands on the surface of quantum dots of an AgBiSTe compound semiconductor in which the crystal structure was cubic and the atomic ratio estimated from the energy dispersive X-ray spectroscopy was Ag:Bi:S:Te=1.4:1.0:1.2:0.8 (a quantum dot dispersion liquid of Production Example 6). The band gap of the quantum dot was estimated from light absorption measurement in the visible to infrared region by using an ultraviolet-visible-near infrared spectrophotometer (V-670, manufactured by JASCO Corporation), and it was approximately 0.78 eV

TABLE 1

| | Kind of | | | Band | Ligand in |
|---|---|---|---|---|---|
| | quantum | Atomic ratio | Crystal | gap | dispersion |
| | dot | in quantum dot | structure | [eV] | liquid |
| Production | AgBiSe | Ag:Bi:Se = | Hexagonal | 0.81 | Dodecane- |
| | | | | | thiol |
| Example 1 | | 1.4:1.0:1.9 | | | Oleylamine |
| Production | AgSbSe | Ag:Sb:Se = | Cubic | 0.76 | Dodecane- |
| | | | | | thiol |
| Example 2 | | 1.5:1.0:1.9 | | | Oleylamine |
| Production | AgBiSTe | Ag:Bi:S:Te = | Cubic | 0.95 | Oleic acid |
| Example 3 | | 1.4:1.0:1.8:0.2 | | | |
| Production | AgBiSTe | Ag:Bi:S:Te = | Cubic | 0.91 | Oleic acid |
| Example 4 | | 1.5:1.0:1.6:0.4 | | | |
| Production | AgBiSTe | Ag:Bi:S:Te = | Cubic | 0.82 | Oleic acid |
| Example 5 | | 1.5:1.0:1.4:0.6 | | | |
| Production | AgBiSTe | Ag:Bi:S:Te = | Cubic | 0.78 | Oleic acid |
| Example 6 | | 1.4:1.0:1.2:0.8 | | | |

[Manufacture of Photodetector Element]

### Example 1

An indium tin oxide (ITO) film having a thickness of 100 nm and a titanium oxide film having a thickness of 20 nm were continuously formed on quartz glass by sputtering. Next, the quantum dot dispersion liquid of Production Example 1 was added dropwise onto the titanium oxide film, and then spin coating was carried out at 2,500 rpm to obtain a quantum dot aggregate film (a step 1).

Next, as the ligand solution, an acetonitrile solution of ethanedithiol (concentration: 0.2 v/v %) was added dropwise onto the quantum dot aggregate film, subsequently allowed to stand for 20 seconds, and subjected to spin drying at 2,500 rpm for 10 seconds to subject the ligand coordinated to the quantum dot to the ligand exchange with ethanedithiol. Next, as the rinsing liquid, acetonitrile was added dropwise onto the quantum dot aggregate film and subjected to spin drying at 2,500 rpm for 20 seconds. Next, toluene was added dropwise onto the quantum dot aggregate film and subjected to spin drying at 2,500 rpm for 20 seconds (a step 2).

The operation of the step 1 and the step 2 as one cycle was repeated for four cycles to form a photoelectric conversion film having a thickness of 50 nm, in which ethanedithiol as a ligand was coordinated to the quantum dot.

Next, the photoelectric conversion film was dried in a glove box for 10 hours.

Next, a dichlorobenzene solution of PTB7 (poly({4,8-bis[(2-ethylhexyl)oxy]benzo[1,2-b:4,5-b′]dithiophen-2,6-diyl}{3-fluoro-2-[(2-ethyl hexyl)carbonyl]thieno[3,4-b]thiophendiyl})) (concentration: 5 mg/mL) was applied onto the photoelectric conversion film by spin coating at 2,000 rpm, and then drying was carried out in a glove box for 10 hours to form a PTB7 film.

Next, a vacuum deposition method through a metal mask was used to form MoO₃ at a thickness of 5 nm and Ag at a thickness of 100 nm on the PTB7 film by continuous vapor deposition, thereby manufacturing a photodiode-type photodetector element.

(Examples 2 to 8) Photodetector elements of Examples 2 to 8 were manufactured according to the same method as Example 1 except that in the step of forming the photoelectric conversion film, the kind of the quantum dot dispersion liquid, the kind of the ligand solution, and the kind of the rinsing liquid were each changed to those described in the following table.

(Comparative Example 1)

A photodetector element was manufactured according to the same method as in Example 1 except that the quantum dot dispersion liquid for the comparative example shown below was used instead of the quantum dot dispersion liquid for Production Example 1.

Quantum dot dispersion liquid for comparative example: A dispersion liquid (concentration of quantum dots: 20 mg/mL) in which oleic acid was coordinated as ligands on the surface of quantum dots of an AgBiS compound semiconductor in which the crystal structure was cubic and the atomic ratio estimated from the energy dispersive X-ray spectroscopy was Ag:Bi:S=1.5:1.0:1.6. The band gap of the AgBiS₂ quantum dot was estimated from light absorption measurement in the visible to infrared region by using an ultraviolet-visible-near infrared spectrophotometer (V-670, manufactured by JASCO Corporation), and it was approximately 1.05 eV.

TABLE 2

| | Kind of | | |
|---|---|---|---|
| | quantum | | |
| | dot | | |
| | dispersion | | Rinsing |
| | liquid | Ligand solution | liquid |
| Example 1 | Production | Acetonitrile solution of ethanedithiol | Acetonitrile |
| | Example 1 | (concentration: 0.2 v/v %) | |
| Example 2 | Production | Acetonitrile solution of ethanedithiol | Acetonitrile |
| | Example 2 | (concentration: 0.2 v/v %) | |
| Example 3 | Production | Acetonitrile solution of ethanedithiol | Acetonitrile |
| | Example 3 | (concentration: 0.2 v/v %) | |
| Example 4 | Production | Acetonitrile solution of ethanedithiol | Acetonitrile |
| | Example 4 | (concentration: 0.2 v/v %) | |
| Example 5 | Production | Acetonitrile solution of ethanedithiol | Acetonitrile |
| | Example 5 | (concentration: 0.2 v/v %) | |
| Example 6 | Production | Acetonitrile solution of ethanedithiol | Acetonitrile |
| | Example 6 | (concentration: 0.2 v/v %) | |
| Example 7 | Production | Methanol solution of | Methanol |
| | Example 5 | mercaptopropionic acid | |
| | | (concentration: 0.2 v/v %) | |
| Example 8 | Production | Methanol solution of thioglycolic | Acetonitrile |
| | Example 5 | acid (concentration: 0.2 v/v %) | |
| | | Methanol solution of zinc iodide | |
| | | (concentration: 25 mmol/L) | |
| Com- | Quantum | Acetonitrile solution of ethanedithiol | Acetonitrile |
| parative | dot | (concentration: 0.2 v/v %) | |
| Example 1 | dispersion | | |
| | liquid for | | |
| | com- | | |
| | parative | | |
| | example | | |

<Evaluation>

External quantum efficiency (EQE) of the manufactured photodetector elements was evaluated by using a semiconductor parameter analyzer (C4156, manufactured by Agilent Technologies, Inc.).

First, the current-voltage characteristics (I-V characteristics) were measured while sweeping the voltage from 0 V to -2 V in a state of not carrying out irradiation with light, and the dark current value was evaluated. Here, regarding the dark current value, a value at -1V was used as the dark current value. Subsequently, the I-V characteristics were measured while sweeping the voltage from 0 V to -2 V in a state of carrying out irradiation with monochrome light of 1,200 nm. A value obtained by subtracting the dark current value from the current value in a state where -1 V was applied was defined as the photocurrent value, and the external quantum efficiency (EQE) was calculated from the photocurrent value.

TABLE 3

| | EQE (%) |
|---|---|
| Example 1 | 3.9 |
| Example 2 | 3.5 |
| Example 3 | 4.1 |
| Example 4 | 5.6 |
| Example 5 | 6.2 |
| Example 6 | 5.8 |
| Example 7 | 7.1 |
| Example 8 | 8.5 |
| Comparative Example 1 | 0.1 |

As shown in the above table, it was confirmed that the external quantum efficiency (EQE) of the photodetector element of Example was significantly high as compared with the external quantum efficiency (EQE) of Comparative Example 1.

In a case where an image sensor is produced by a known method by using the photodetector element obtained in Example described and incorporating it into a solid-state imaging element together with an optical filter produced according to the methods disclosed in WO2016/186050A and WO2016/190162A, it is possible to obtain an image sensor having good visible and infrared imaging performance.

Explanation of References
1: photodetector element
11: upper electrode
12: lower electrode
13: photoelectric conversion film

What is claimed is:

1. A photoelectric conversion film comprising a quantum dot of a compound semiconductor that contains an Ag element, at least one element selected from an Sb element or a Bi element, and at least one element selected from an Se element or a Te element.

2. The photoelectric conversion film according to claim 1,
wherein the compound semiconductor contains an Ag element, a Bi element, and at least one element selected from an Se element or a Te element.

3. The photoelectric conversion film according to claim 1,
wherein the compound semiconductor contains an Ag element, a Bi element, and a Te element.

4. The photoelectric conversion film according to claim 1,
wherein the compound semiconductor further contains an S element.

5. The photoelectric conversion film according to claim 1,
wherein the compound semiconductor contains an Ag element, at least one element selected from an Sb element or a Bi element, a Te element, and an S element, and a value obtained by dividing the number of the Te elements by a total of the number of the Te elements and the number of the S elements is 0.05 to 0.5.

6. The photoelectric conversion film according to claim 1,
wherein a crystal structure of the compound semiconductor is a cubic system or a hexagonal system.

7. The photoelectric conversion film according to claim 1,
wherein a band gap of the quantum dot is 1.2 eV or less.

8. The photoelectric conversion film according to claim 1,
wherein a band gap of the quantum dot is 1.0 eV or less.

9. The photoelectric conversion film according to claim 1,
wherein an average particle diameter of the quantum dots is 3 to 20 nm.

10. The photoelectric conversion film according to claim 1, further comprising a ligand that is coordinated to the quantum dot.

11. The photoelectric conversion film according to claim 10,
wherein the ligand includes at least one selected from a ligand containing a halogen atom or a polydentate ligand containing two or more coordination moieties.

12. The photoelectric conversion film according to claim 11,
wherein the ligand containing a halogen atom is an inorganic halide.

13. A dispersion liquid for forming a photoelectric conversion film, the dispersion liquid comprising:
a quantum dot of a compound semiconductor that contains an Ag element, at least one element selected from an Sb element or a Bi element, and at least one element selected from an Se element or a Te element;
a ligand that is coordinated to the quantum dot; and
a solvent.

14. A photodetector element comprising the photoelectric conversion film according to claim 1.

15. An image sensor comprising the photodetector element according to claim 14.
